(19) United States
(12) Patent Application Publication
(10) Pub. No.: US 2026/0074000 A1
(43) Pub. Date: Mar. 12, 2026

(54) STORAGE DEVICE AND OPERATING METHOD OF THE SAME

(71) Applicant: SAMSUNG ELECTRONICS CO., LTD., Suwon-si (KR)

(72) Inventor: Jongho Kim, Suwon-si (KR)

(73) Assignee: SAMSUNG ELECTRONICS CO., LTD., Suwon-si (KR)

(21) Appl. No.: 19/321,876

(22) Filed: Sep. 8, 2025

(30) Foreign Application Priority Data
Sep. 10, 2024 (KR) 10-2024-0123341

(51) Int. Cl. G11C 16/34; G11C 16/08; G11C 16/10; G11C 16/26; G11C 29/02

(52) U.S. Cl. CPC G11C 16/3459; G11C 16/08; G11C 16/102; G11C 16/26; G11C 29/022

(57) ABSTRACT

Provided is a storage device including a memory device including a plurality of memory blocks, the memory device being configured to store data or read data, and at least one processor configured to control the memory device and to execute a data input/output request from a host, wherein the memory device further includes a row decoder configured to apply a voltage of a first level to a first wordline, and a plurality of page buffers, wherein, based on the voltage of the first level being applied to the first wordline, the plurality of page buffers are configured to temporarily store first sensing data sensed from a plurality of bitlines at a first time and second sensing data sensed from the plurality of bitlines at a second time after the first time.

### CROSS-REFERENCE TO RELATED APPLICATION

This application claims priority to Korean Patent Application No. 10-2024-0123341 filed on Sep. 10, 2024, in the Korean Intellectual Property Office, the disclosure of which is incorporated by reference herein in its entirety.

### BACKGROUND

Embodiments of the present disclosure relate to a storage device and an operating method thereof, and more particularly, relate to a storage device capable of determining a defect of a wordline and an operating method thereof.

As a semiconductor device-based storage device offers high input/output (I/O) performance and low energy consumption compared to a hard disk drive (HDD), the use of the semiconductor-based nonvolatile memory device is being used as a storage device in a data center and a cloud computing environment where multiple users share resources.

As the size of data to be processed by an electronic device increases, a larger storage space is being required. To cope with this demand, a three-dimensional memory device with the high degree of integration is being used as a storage space. Also, the reliability of the memory device may become more important.

### SUMMARY

One or more embodiments provide a semiconductor-based storage device capable of determining a defect of a wordline and an operating method thereof.

According to an aspect of one or more embodiments, there is provided a storage device including a memory device including a plurality of memory blocks, the memory device being configured to store data or read data, and at least one processor configured to control the memory device and to execute a data input/output request from a host, wherein the memory device further includes a row decoder configured to apply a voltage of a first level to a first wordline, and a plurality of page buffers, wherein, based on the voltage of the first level being applied to the first wordline, the plurality of page buffers are configured to temporarily store first sensing data sensed from a plurality of bitlines at a first time and second sensing data sensed from the plurality of bitlines at a second time after the first time.

According to another aspect of one or more embodiments, there is provided a storage device including a memory device configured to store data or read data, and at least one processor configured to control the memory device and to execute a data input/output request provided from a host, wherein the memory device includes a plurality of memory blocks, a row decoder configured to apply a voltage to a plurality of wordlines electrically connected to the plurality of memory blocks, a plurality of page buffers configured to temporarily store pieces of data sensed from a plurality of bitlines, and a control logic circuit configured to control the row decoder, wherein the control logic circuit is configured to perform a first read operation for at least one wordline at a first time under a first condition, and perform a second read operation for the at least one wordline at a second time under a second condition, wherein the plurality of page buffers are further configured to temporarily store first sensing data by the first read operation and second sensing data by the second read operation, wherein a level of a voltage applied to the at least one wordline under the first condition is identical to a level of a voltage applied to the at least one wordline under the second condition, and wherein a time during which the level of the voltage applied to the at least one wordline under the first condition is stabilized is different from a time during which the level of the voltage applied to the at least one wordline under the second condition is stabilized.

According to still another aspect of one or more embodiments, there is provided an operating method of a nonvolatile memory system, the method including sensing cells electrically connected to a first wordline at a first time based on a first voltage, performing a first cell counting operation based on first sensing data sensed at the first time, storing a first cell count being a result of the first cell counting operation, sensing the cells electrically connected to the first wordline at a second time following the first time based on the first voltage, performing a second cell counting operation based on second sensing data sensed at the second time, storing a second cell count being a result of the second cell counting operation, and comparing the first cell count and the second cell count.

### BRIEF DESCRIPTION OF DRAWINGS

Embodiments will be more clearly understood from the following detailed description taken in conjunction with the accompanying drawings in which:

FIG. 1 is a block diagram describing a storage device according to one or more embodiments;

FIGS. 2, 3, and 4 are diagrams describing a characteristic of a defective wordline as an example;

FIGS. 5 and 6 are diagrams describing methods in which a storage device according to one or more embodiments determines a defective wordline, as an example;

FIG. 7 is a diagram illustrating a configuration of a memory device according to one or more embodiments;

FIG. 8 is a diagram illustrating a configuration of a memory block according to one or more embodiments;

FIG. 9 is a block diagram describing an embodiment of a memory controller according to one or more embodiments;

FIG. 10 is a diagram describing an operating method of a memory controller according to the embodiment of FIG. 9;

FIG. 11 is a diagram illustrating a configuration of a memory device according to one or more embodiments;

FIG. 12 is a block diagram describing a cell counter of a memory device of FIG. 11;

FIG. 13 is a diagram illustrating a configuration of a memory device according to one or more embodiments;

FIG. 14 is a diagram describing an operation in which a storage device according to one or more embodiments obtains sensing data of a partial area of a memory cell array;

FIG. 15 is a diagram describing an operation of programming a memory cell, according to one or more embodiments;

FIG. 16 is a diagram describing an operation of determining a defective wordline, according to one or more embodiments;

FIG. 17 is a diagram describing an operating method of a storage device according to one or more embodiment;

FIGS. 18 and 19 are diagrams describing operating methods of a storage device according to one or more embodiments in two different modes;

FIG. 20 is a diagram describing an operating method of a storage device according to one or more embodiments; and

FIGS. 20, 21, and 22 are diagrams for describing an environment in which operating methods according to one or more embodiments are performed.

### DETAILED DESCRIPTION

Below, embodiments of the present disclosure will be described in detail and clearly to such an extent that an ordinary one in the art easily carries out the present disclosure.

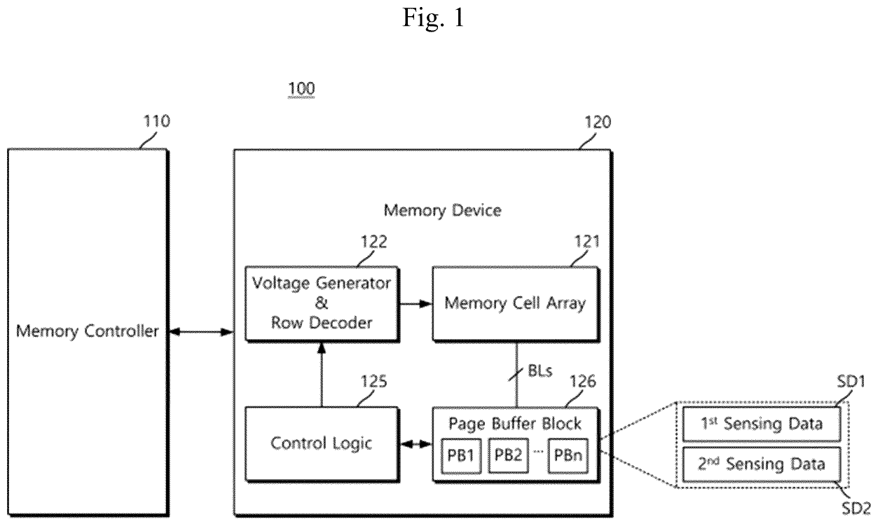

FIG. 1 is a block diagram illustrating a storage device 100 according to one or more embodiments. The storage device 100 according to one or more embodiments will be described with reference to FIG. 1.

The storage device 100 according to one or more embodiments may determine a defect of at least one wordline of a memory cell array 121. The storage device 100 may perform a plurality of cell counting operations for a wordline to which the same voltage is applied at different times and may determine a defect of the wordline, based on a result of comparing a plurality of cell counts. This will be described in detail with reference to FIG. 1.

The description will be given in detail with reference to FIG. 1. Referring to FIG. 1, the storage device 100 may include a memory controller 110 and a memory device 120.

The storage device 100 may be an internal memory embedded in an electronic device. For example, the storage device 100 may include a solid state drive (SSD), an embedded universal flash storage (UFS) device, or an embedded multi-media card (eMMC).

As another example, the storage device 100 may be an external storage device removable from an electronic device. For example, the storage device 100 may include a universal flash storage (UFS) memory card, a compact flash (CF) card, a secure digital (SD) card, a micro-SD card, a mini-SD card, an extreme digital (xD) card, or a memory stick.

However, embodiments are not limited thereto. According to one or more embodiments, the storage device 100 may be referred to as a “personal computer,” a “data server,” “network attached storage” (NAS),” an “Internet of Things (IoT) device,” a “portable electronic device”, etc.

The storage device 100 may be electrically connected to a host so as to be used by the host, and the storage device 100 may be accessed through a direct media access (DMA) of any other device in addition to the host.

The storage device 100 may be implemented in a state of being physically separated from the host or may be implemented with the form factor mounted on the same package as the host. For example, the storage device 100 may be implemented based on the E1.S, E1.L, E3.S, E3.L, or PCIe AIC (CEM) form factor. As another example, the storage device 100 may be implemented based on the U.2 form factor, the M.2 form factor, or any other PCIe form factor.

The storage device 100 may be coupled such that it is possible to communicate with any other components of the host through a storage interface bus. According to one or more embodiments, the storage device 100 may be directly mounted on a physical port which is based on the peripheral component interconnect express (PCIe). The storage interface bus may be, for example, a PCIe bus. The host may exchange data with the storage device 100 through the storage interface bus by using a storage interface protocol. The data may include user data. The storage interface protocol may be, for example, a compute express link (CXL) protocol and/or a non-volatile memory host controller express (NVMe) protocol.

The memory controller 110 may control the memory device 120 to perform a request received from the host. The request may include a request for a write operation, a read operation, and/or an erase operation of user data. The write operation may be referred to as a “record, store, and/or program operation.” In the specification, the expression “the memory controller 110 programs data” is used to indicate the memory controller 110 controlling the memory device 120 to program data in the memory device 120. The data may be user data or may be any other preset pattern data.

The memory device 120 may include a flash memory of a two-dimensional (2D) structure or a two-dimensional (3D) structure. The flash memory may include different types of nonvolatile memories such as, for example, a NAND flash memory, a vertical NAND (V-NAND) flash memory, a NOR flash memory, a magnetic RAM (MRAM), a phase-change RAM (PRAM), a ferroelectric random access memory (FRAM), a spin transfer torque random access memory (STT-RAM), and/or a resistive RAM (RRAM).

The memory controller 110 may control the memory device 120 depending on a request of an external device (e.g., a host). For example, the memory controller 110 may transmit an address and a command to the memory device 120 depending on the request of the external device. The memory controller 110 may exchange data with the memory device 120 depending on the request of the external device.

The memory device 120 may include a memory cell array 121, and the memory cell array 121 may include a plurality of blocks BLK1 to BLKm. Each of the plurality of blocks BLK1 to BLKm may include a plurality of memory cells. Each of the plurality of memory cells may be a single level cell (SLC) storing 1-bit data or may be a multi-level cell (MLC) storing 2-bit data. Alternatively, each of the plurality of memory cells may be a triple level cell (TLC) storing 3-bit data may be a quadruple level cell (QLC) storing 4-bit data. According to one or more embodiments, the size of data stored in a memory cell may not be specifically limited, and a memory cell may store various sizes of bit data.

In one or more embodiments, a voltage generator and row decoder 122 of the memory device 120 may apply a first voltage to a selected wordline under control of control logic 125. For example, the voltage generator and row decoder 122 may apply a pulse having a voltage of a first level to the selected wordline. The first voltage is applied to control gates of cells electrically connected to the selected wordline. For example, the first voltage may be applied to control gates of cells of the same page. As another example, the first voltage may be applied to control gates of cells of a plurality of pages connected to the same wordline.

In one or more embodiments, the voltage of the first level may be a voltage whose level is the same as a verify level. The voltage of the first level may be a voltage whose level is the same as a read level. For example, when a memory cell is a multi-level cell MLC, a triple level cell TLC, or a quadruple level cell QLC, the voltage of the first level may be a voltage whose level is the same as one of a plurality of program verify levels. The voltage of the first level may be a voltage whose level is the same as a plurality of read levels.

A page buffer block 126 may perform a plurality of sensing operations for the selected wordline. For example, the page buffer block 126 may store first sensing data SD1 obtained by sensing cell data of cells connected to the selected wordline during a first time in at least some of page buffer circuits PB1, PB2, . . . , PBn and may store second sensing data SD2 sensed during a second time in at least others of page buffer circuits PB1, PB2, . . . , PBn. During the first time and the second time, there is a state where the first voltage of the same magnitude is applied the selected wordline.

The first time and the second time are different times. For example, the second time may be a time following the first time.

In one or more embodiments, the page buffer block 126 may transmit the first sensing data SD1 and the second sensing data SD2 to the control logic 125 or may transmit the first sensing data SD1 and the second sensing data SD2 to the memory controller 110 through an input/output circuit. The control logic 125 or the memory controller 110 may perform the cell counting operation based on each of the first sensing data SD1 and the second sensing data SD2.

As another example, the page buffer block 126 may perform the cell counting operation based on each of the first sensing data SD1 and the second sensing data SD2. The page buffer block 126 may transmit a cell count, which is based on each of the first sensing data SD1 and the second sensing data SD2, to the control logic 125 or may transmit the cell count to the memory controller 110 through the input/output circuit.

The cell counting operation may be an operation of counting the number of on-cells among memory cells connected to wordlines to which the voltage of the first level is applied. However, embodiments are not limited thereto. The storage device 100 may count the number of off-cells among memory cells connected to wordlines to which the voltage of the first level is applied and may calculate (obtain) the number of on-cells by subtracting the number of off-cells from the number of memory cells. As another example, the storage device 100 may determine a defect of a wordline based on the number of off-cells.

In one or more embodiments, the control logic 125 and/or the memory controller 110 may determine a defect of a wordline based on a result of comparing a first cell count based on the first sensing data SD1 and a second cell count based on the second sensing data SD2. For example, when a difference between the first cell count and the second cell count is greater than or equal to a preset reference value, the control logic 125 and/or the memory controller 110 may determine that the selected wordline is defective.

Embodiments are not limited to the method of applying a voltage of the same magnitude to a selected wordline and to determine a defect of the selected wordline through a comparison result of cell counts based on a plurality of sensing operations.

For example, the storage device 100 may perform a plurality of read operations for a wordline to which the same voltage is applied at different times. The storage device 100 may determine a defect of the wordline, based on a result of comparing error bits of the pieces of read data.

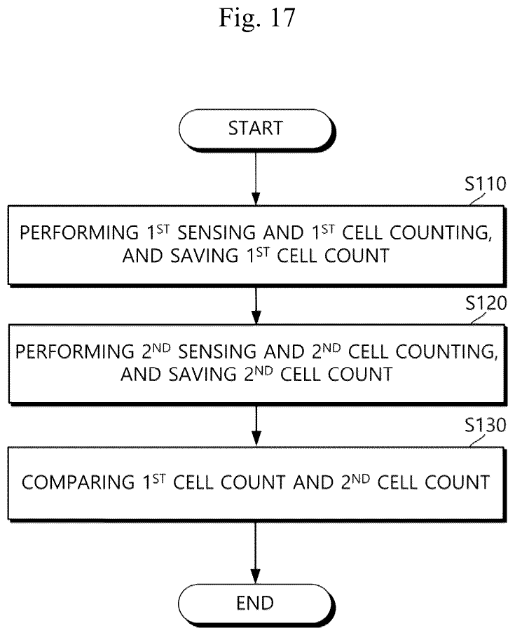

As another example, for another example, the storage device 100 may obtain a threshold voltage value which reaches the same number of on-cells at different times, which will be described with reference to FIG. 17. For example, the storage device 100 may determine a defect of a wordline, based on a result of comparing a first threshold voltage value and a second threshold voltage value reaching the given number of on-cells under respective conditions different from each other.

When a voltage of the same magnitude is applied, a time taken for a wordline of a specific defect type to reach a target level may be longer than a time taken for a normal (non-defective) wordline to reach the target level. Accordingly, before a defective wordline reaches the target level, a voltage difference between the target level and a voltage of the defective wordline may be greater than a voltage difference between the target level and a voltage of the normal wordline. According to the above description, for example, even though a voltage of the same magnitude is applied to a defective wordline, the number of memory cells determined as an on-cell may vary depending on a time during which memory cells connected to a wordline are sensed.

One or more embodiments may determine a defect of a wordline based on a characteristic of the defective wordline, for example, by comparing pieces of sensing data obtained at different times based on a plurality of sensing operations. As another example, it may be possible to determine a defect of a selected wordline within a relatively short time by using a voltage of a program verify level or a voltage of a read level. For example, a resistive defect of a wordline may be determined within a relatively short time.

Based on the characteristic of the defective wordline, in one or more embodiments, the storage device 100 may determine a defect of a wordline based on sensing data obtained at an earlier read sensing time than a normal read sensing time. For example, while a normal read operation is typically performed at a first time after the target voltage is applied to the wordline, the storage device 100 may perform sensing at a second time after the target voltage is applied to the wordline, where the second time is earlier than the first time. The sensing data obtained at the second time, which is earlier than the normal read sensing time, may be referred to as early sensing data. The storage device 100 may determine whether the wordline is defective based on the early sensing data. For example, the storage device 100 may compare an on-cell count or an off-cell count based on the early sensing data with a predetermined threshold. If, for example, the on-cell count of the early sensing data exceeds the predetermined threshold, the storage device 100 may determine that the corresponding wordline is defective.

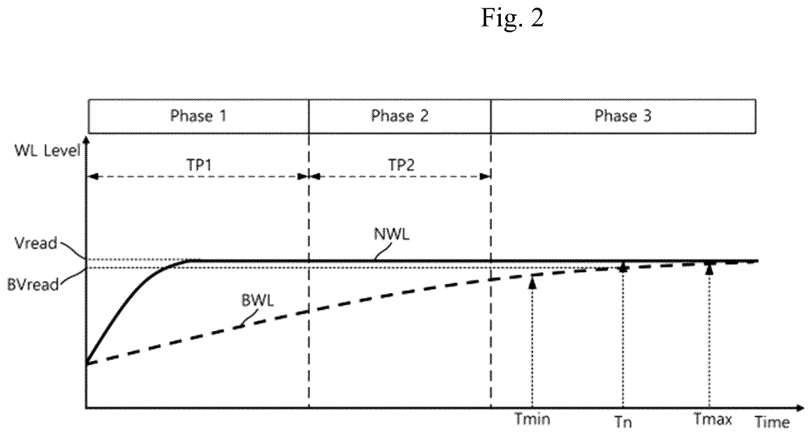

FIGS. 2 to 4 are diagrams describing a characteristic of a defective wordline as an example.

FIG. 2 shows a change in a wordline voltage of each of a normal wordline NWL and a defective wordline BWL when a voltage Vread of a read level is applied to a wordline. For example, the defective wordline BWL may be a wordline of a resistive defect type.

FIG. 2 shows a change in a wordline voltage in a first phase 1 being a page buffer initialization phase, a second phase 2 being a bitline precharge phase, and a third phase 3 being a develop and sensing phase. The first phase 1 may be maintained during a first phase time TP1, and the second phase 2 may be maintained during a second phase time TP2. Accordingly, the third phase 3 may start after a time corresponding to a sum of the first phase time TP1 and the second phase time TP2. The ratio of the first phase 1 and the second phase Phase 2 illustrated in FIG. 2 is provided as an example for description, and the actual ratio of the first phase Phase 1 and the second phase Phase 2 may be different from that in FIG. 2.

Referring to FIG. 2, when the voltage Vread of the read level being a target voltage is applied to a wordline, a voltage of the normal wordline NWL reaches the voltage Vread of the read level in the first phase Phase 1. Accordingly, because the voltage of the normal wordline NWL maintains the voltage Vread of the read level being the target voltage at a typical sensing time Tn for the read operation, a more accurate sensing of a memory cell is possible.

However, a voltage of the defective wordline BWL may fail to reach the voltage Vread of the read level even in the first phase Phase 1 and the second phase Phase 2, and may continuously increase. The voltage of the defective wordline BWL may continue to increase even in the third phase Phase 3 being the develop and sensing phase. Accordingly, at a typical sensing time Tn for the read operation, the defective wordline BWL may have a voltage BVread lower in level than the voltage Vread of the read level. Accordingly, at the typical sensing time Tn for the read operation, a sensing result for the defective wordline BWL may not be accurate.

For example, even though memory cells belong to the same distribution, when threshold voltages with different magnitudes are applied to the memory cells, sensing results may be different from each other. For example, a result of the read operation may differ.

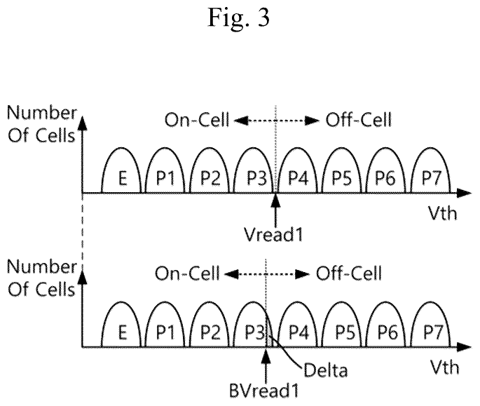

FIG. 3 shows results of the read operation when threshold voltages with different magnitudes are applied to memory cells even though the memory cells belong to the same distribution.

In the case of sensing memory cells by using a voltage Vread1 of a normal read level, each of memory cells of an erase state “E” and memory cells whose program states are a first program state P1, a second program state P2, and a third program state P3 may form a channel. For example, all memory cells whose threshold voltages are lower than the voltage Vread1 of the normal read level may be determined as an on-cell.

However, in the case of sensing memory cells by using a voltage BVread1 lower in level than the voltage Vread1 of the normal read level as a threshold voltage, some of the memory cells whose program state is the third program state P3 may not form a channel. For example, some of the memory cells whose program state is the third program state P3 may be determined as an off-cell, not an on-cell.

Returning to FIG. 2, a voltage of the defective wordline BWL at a first time Tmin and a voltage of the defective wordline BWL at a second time Tmax may be different from each other. For example, in FIG. 2, the voltage of the defective wordline BWL at the first time Tmin is lower than the voltage BVread, and the voltage of the defective wordline BWL at the second time Tmax is higher than the voltage BVread.

Accordingly, a result of sensing the memory cells connected to the defective wordline BWL at the first time Tmin earlier than the typical sensing time Tn may be different from a result of sensing the memory cells connected to the defective wordline BWL at the second time Tmax later than the typical sensing time Tn. As described with reference to FIG. 3, even though the voltage Vread of the read level being the target voltage is applied to the defective wordline BWL, some of memory cells forming a channel at the second time Tmax from among the memory cells connected to the defective wordline BWL may not form a channel at the first time Tmin. For example, the number of memory cells determined as an on-cell at the first time Tmin from among the memory cells connected to the defective wordline BWL may be different from the number of memory cells determined as an on-cell at the second time Tmax from among the memory cells connected to the defective wordline BWL.

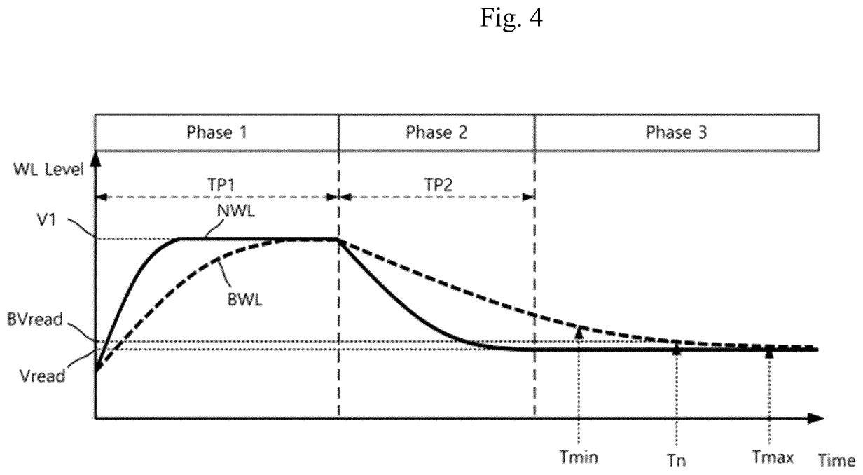

FIG. 4 shows an example of the read operation, in which a voltage V1 of a uniform level is first applied to each of the normal wordline NWL and the defective wordline BWL and the voltage Vread of the read level is secondarily applied to each of the normal wordline NWL and the defective wordline BWL.

In FIG. 4, the first phase time TP1 during which the first phase Phase 1 being a page buffer initialization phase is maintained and the second phase time TP2 during which the second phase Phase 2 being a bitline precharge phase is maintained may be the same as or different from the first phase time TP1 and the second phase time TP2 of FIG. 2. The ratio of the first phase Phase 1 and the second phase Phase 2 illustrated in FIG. 4 is provided as an example, and a ratio of the first phase Phase 1 and the second phase Phase 2 may be different from that in FIG. 4.

Referring to FIG. 4, in the first phase Phase 1, the defective wordline BWL reaches the voltage V1 of the uniform level at a later time than the normal wordline NWL. Also, in the third phase Phase 3 being a develop and sensing phase, the defective wordline BWL reaches the voltage Vread of the read level at a later time than the normal wordline NWL. For example, in a partial period of the third phase Phase 3, the voltage level of the defective wordline BWL may continuously decrease.

Accordingly, as described with reference to FIG. 2, even though the voltages of FIG. 4 are applied for the read operation, a result of sensing the memory cells connected to the defective wordline BWL at the first time Tmin earlier than the typical sensing time Tn may be different from a result of sensing the memory cells connected to the defective wordline BWL at the second time Tmax later than the typical sensing time Tn. For example, the number of memory cells determined as an on-cell at the first time Tmin from among the memory cells connected to the defective wordline BWL may be different from the number of memory cells determined as an on-cell at the second time Tmax from among the memory cells connected to the defective wordline BWL.

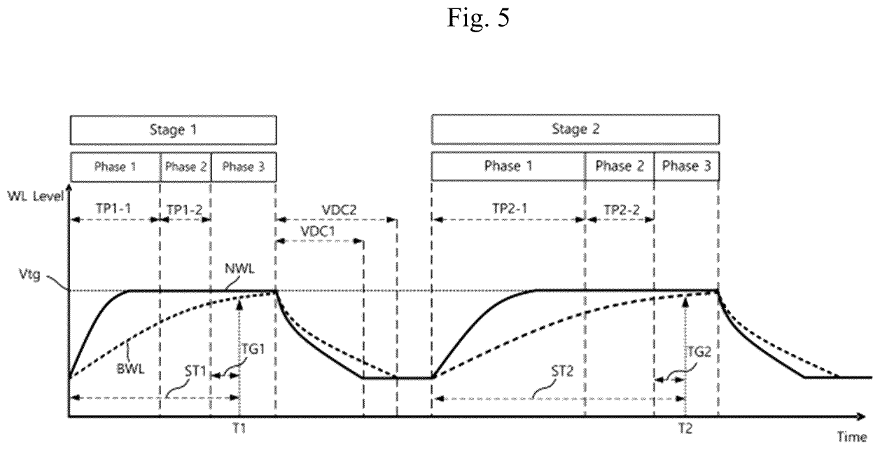

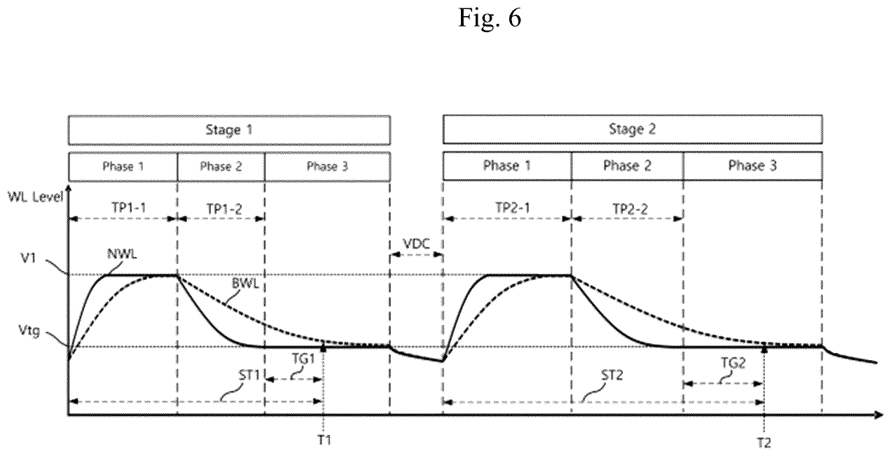

FIGS. 5 and 6 are diagrams describing methods in which a storage device according to one or more embodiments determines a defective wordline, as an example. For example, the defective wordline determining methods to be described with reference to FIGS. 5 and 6 may be performed by the storage device 100 of FIG. 1. The methods in which the storage device 100 determines a defective wordline will be described with reference to FIGS. 1, 5, and 6.

FIG. 5 shows a situation in which the voltage level of the defective wordline BWL continuously increases in a partial period of the third phase Phase 3, and FIG. 6 shows a situation in which the voltage level of the defective wordline BWL continuously decreases in a partial period of the third phase Phase 3.

Referring to FIG. 5, to determine a defective wordline, the storage device 100 applies a target voltage Vtg to a selected wordline in each of two different stages. Each stage may include three phases. Periods VDC1 and VDC2 in which a voltage level of a wordline decreases from the target voltage Vtg may exist between the stages. For example, the target voltage Vtg may be applied to the selected wordline in the first stage and the application of the target voltage Vtg to the selected wordline may be stopped after a first setting time passes from first sensing, and thus, the voltage level of the selected wordline may decrease. After a second setting time passes from the stop of the application of the target voltage Vtg, the target voltage Vtg may be again applied to the selected wordline in the second stage.

Referring to FIG. 6, to determine a defective wordline, in each of different stages, the storage device 100 first applies the voltage V1 of the uniform level to the selected wordline and secondarily applies the target voltage Vtg to the selected wordline. A period VDC in which a voltage level of a wordline decreases from the target voltage Vtg may exist between the stages. For example, the target voltage Vtg may be applied to the selected wordline in the first stage and the application of the target voltage Vtg to the selected wordline may be stopped after a first setting time from first sensing, and thus, the voltage level of the selected wordline may decrease. After a second setting time from the stop of the application of the target voltage Vtg, in the second stage, the voltage V1 of the uniform level may be first applied to the selected word line, and the target voltage Vtg may be again applied to the selected wordline.

Referring to FIG. 5, each stage may include the first phase Phase 1 in which a target voltage is applied, the second phase Phase 2 in which a voltage level of a wordline is stabilized to the target voltage, and the third phase Phase 3 in which sensing is performed. The third phase Phase 3 may be referred to as a sensing phase.

Referring to FIG. 6, each stage may include the first phase Phase 1 in which a first voltage higher in level than the target voltage is applied, the second phase Phase 2 in which a voltage level a wordline is stabilized, and the third phase Phase 3 in which sensing is performed. In the second phase Phase 2 of FIG. 6, the first voltage may be discharged, and the application of the target voltage may be started. The third phase Phase 3 may be referred to as a sensing phase.

In one or more embodiments, in the first phase Phase 1, a page buffer initialization operation may be performed. In the second phase Phase 2, a bitline precharge operation may be performed. In the third phase Phase 3, a bitline develop operation may be performed. However, embodiments are not limited thereto, and for example, each of the page buffer initialization operation, the bitline precharge operation, and the bitline develop operation may be partially performed through a plurality of phases. For example, the page buffer initialization operation may be partially performed in a portion of the first phase Phase 1 and may be partially performed in a portion of the second phase Phase 2.

The storage device 100 according to one or more embodiments may differently maintain a holding time of a phase of the same kind in each of a first stage Stage 1 and a second stage Stage 2.

For example, referring to FIGS. 5 and 6, a holding time TP1-1 of the first phase Phase 1 in the first stage Stage 1 may be equal to or shorter than a holding time TP2-1 of the first phase Phase 1 in the second stage Stage 2. A holding time TP1-2 of the second phase Phase 2 in the first stage Stage 1 may be equal to or shorter than a holding time TP2-2 of the second phase Phase 2 in the second stage Stage 2.

As another example, referring to FIGS. 5 and 6, a sum of the holding time TP1-1 of the first phase Phase 1 and the holding time TP1-2 of the second phase Phase 2 in the first stage Stage 1 may be shorter than a sum of the holding time TP2-1 of the first stage Stage 1 and the holding time TP2-2 of the second phase Phase 2 in the second stage Stage 2.

In one or more embodiments, referring to FIGS. 5 and 6, a time interval TG1 from a start time of the third phase Phase 3 in the first stage Stage 1 to a first time T1 when first sensing is performed may be equal to a time interval TG2 from a start time of the third phase Phase 3 in the second stage Stage 2 to a second time T2 when second sensing is performed.

Accordingly, referring to FIGS. 5 and 6, a time interval ST1 from the start time of the first stage Stage 1 to the first time T1 may be shorter than a time interval ST2 from the start time of the second stage Stage 2 to the second time T2.

According to the above description, referring to FIGS. 5 and 6, even though the target voltage Vtg of the same magnitude is applied to a wordline, the voltage level of the defective wordline BWL at the first time T1 may be different from the voltage level of the defective wordline BWL at the second time T2. The voltage level of the normal wordline NWL at the first time T1 may be equal or substantially equal to the voltage level of the normal wordline NWL at the second time T2.

Accordingly, the storage device 100 may determine whether the selected wordline is defective, based on first sensing data obtained by sensing the memory cells electrically connected to the selected wordline at the first time T1 and second sensing data obtained by sensing the memory cells electrically connected to the selected wordline at the second time T2.

For example, the storage device 100 may compare a difference between the first number of on-cells based on the first sensing data and the second number of on-cells based on the second sensing data with a preset reference. When the comparison result exceeds the preset reference, the storage device 100 may determine that the selected wordline is a defective wordline. However, embodiments are not limited thereto, and for example, the storage device 100 the compare a difference between the first number of off-cell data are based on the first sensing data and the second number of off-cells based on the second sensing data with the preset reference.

The storage device 100 may determine the defect of the selected wordline by using various factors, in addition to the number of on-cells and/or the number of off-cells. For example, the storage device 100 may determine the defect of the selected wordline by using various characteristics which are based on pieces of sensing data obtained by sensing memory cells connected to the selected wordline at different sensing times. For example, the storage device 100 may compare the numbers of error bits, which are determined by using the error correction code, based on the pieces of sensing data and may determine the defect of the selected wordline. Accordingly, to determine the defect of the selected wordline, any factors whose values vary when a level of a voltage applied to a wordline is changed may be used, in addition to the factor(s) described above.

In one or some embodiments, the storage device 100 may determine whether the wordline is defective based on sensing data obtained at the first time T1. The second time T2 may correspond to a typical sensing time, whereas the first time T1 may be an earlier sensing time than the typical sensing time. As described with reference to FIG. 1, the storage device 100 may compare the on-cell count or the off-cell count of early sensing data obtained at the first time T1 with a predetermined threshold to determine whether the wordline is defective.

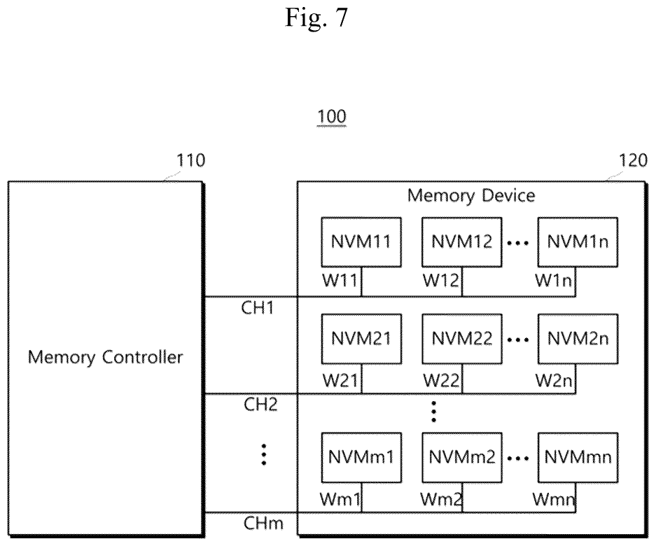

FIG. 7 is a diagram illustrating a configuration of a memory device according to one or more embodiments. The storage device 100 of FIG. 7 may correspond to the storage device 100 of FIG. 1.

The memory controller 110 may perform an I/O for a plurality of memory devices NVM11 to NVMmn through a plurality of channels CH1 to CHm. The memory device 120 and the memory controller 110 may be connected through the plurality of channels CH1 to CHm. In one or more embodiments, the memory controller 110 may include a plurality of controller modules respectively corresponding to the plurality of channels CH1 to CHm.

The memory controller 110 may control a nonvolatile memory device (e.g., one of NVM11 to NVMmn) connected to one of the plurality of channels CH1 to CHm through a way.

The memory controller 110 may exchange signals with the memory device 120 through the plurality of channels CH1 to CHm.

The memory device 120 may include the plurality of nonvolatile memory devices NVM11 to NVMmn. Each of the nonvolatile memory devices NVM11 to NVMmn may be a nonvolatile memory package. In one or more embodiments, each of the nonvolatile memory devices NVM11 to NVMmn may include a plurality of dies, but the embodiments are not limited thereto.

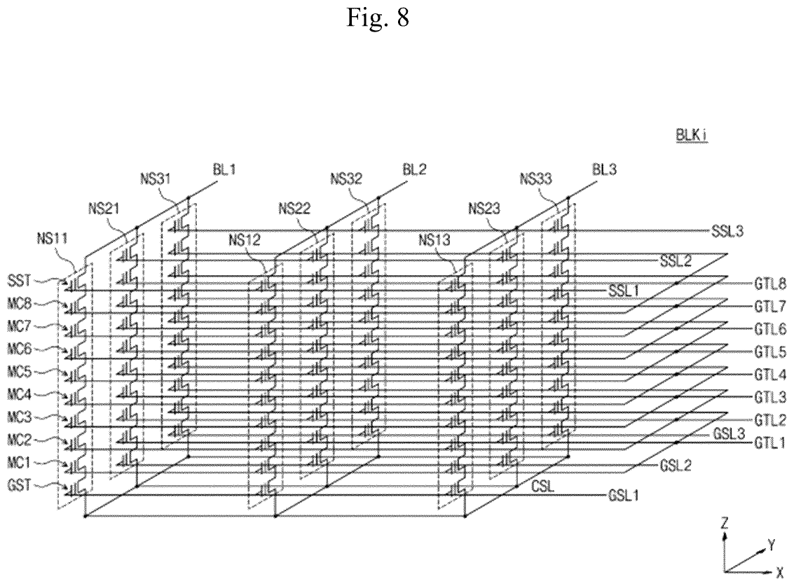

FIG. 8 is a diagram illustrating a configuration of a memory block according to one or more embodiments. A memory block BLKi of FIG. 8 may be one of memory blocks included in the memory cell array 121 of the memory device 120 of FIG. 1.

When the memory device 120 of the storage device 100 of FIG. 1 is implemented with a flash memory of a 3D V-NAND type, each of a plurality of memory blocks constituting the memory device 120 may be expressed by an equivalent circuit illustrated in FIG. 8.

The memory block BLKi illustrated in FIG. 8 indicates a three-dimensional memory block formed on a substrate in a three-dimensional structure. For example, a plurality of memory NAND strings included in the memory block BLKi may be formed in a direction perpendicular to the substrate.

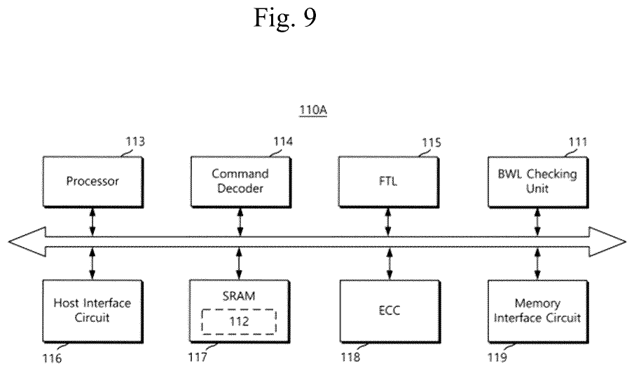

Referring to FIG. 8, the memory block BLKi may include a plurality of memory NAND strings NS11 to NS33 connected between bitline BL1, BL2, and BL3 and a common source line CSL. Each of the plurality of memory NAND strings NS11 to NS33 may include a string selection transistor SST, a plurality of memory cells MC1, MC2, . . . , MC8, and a ground selection transistor GST. An embodiment in which each of the plurality of memory NAND strings NS11 to NS33 includes eight memory cells MC1, MC2, . . . , MC8 is illustrated in FIG. 9, but one or more embodiments is not limited thereto.

The string selection transistor SST may be connected to a corresponding one of string select lines SSL1, SSL2, and SSL3. The plurality of memory cells MC1, MC2, . . . , MC8 may be respectively connected to gate lines GTL1, GTL2, . . . , GTL8. The gate lines GTL1, GTL2, . . . , GTL8 may correspond to wordlines, and at least one of the gate lines GTL1, GTL2, . . . , GTL8 may correspond to a dummy wordline. The ground selection transistor GST may be connected to a corresponding one of ground select lines GSL1, GSL2, and GSL3. The string selection transistor SST may be connected to a corresponding bitline among the bitlines BL1, BL2, and BL3, and the ground selection transistor GST may be connected to the common source line CSL.

Wordlines (e.g., WL1) at the same height may be connected in common, and the ground select lines GSL1, GSL2, and GSL3 and the string select lines SSL1, SSL2, and SSL3 may be separated from each other. An example in which the memory block BLKi is connected to eight gate lines GTL1, GTL2, . . . , GTL8 and three bitlines BL1, BL2, and BL3 is illustrated in FIG. 8, but embodiments are not limited thereto.

The bit density of the memory block BLKi may vary depending on the number of bits which each of the memory cells included in the memory block BLKi stores.

FIG. 9 is a block diagram describing a memory controller according to one or more embodiments. A memory controller 110A to be described with reference to FIG. 9 may correspond to the memory controller 110 of the storage device 100 of FIG. 1.

The memory controller 110A may include a processor 113, a command decoder 114, a flash translation layer 115, a defective wordline checking unit 111, a host interface circuit 116, an SRAM 117, an error correction code (ECC) circuit 118, and a memory interface circuit 119. Although not illustrated in FIG. 9, the memory controller 110A may include a packet manager and/or a working memory device.

The processor 113 may be implemented with a circuit, logic, or a code or a combination thereof. The processor 113 overall controls operations of the storage device 100 including the memory controller 110A. When the storage device 100 is driven, the processor 113 may load the firmware stored in a read only memory (ROM) to the working memory device and may perform all the operations of the memory controller 110. The processor 113 may load the flash translation layer 115 to the working memory device; based on an address translation result of the flash translation layer 115, the processor 113 may program data in the memory device 120 and/or may read data from the memory device 120.

The memory controller 110A may communicate with the host through the host interface circuit 116. The host interface circuit 116 may be implemented with various interface manners such as advanced technology attachment (ATA), serial ATA (SATA), external SATA (e-SATA), small computer small interface (SCSI), serial attached SCSI (SAS), peripheral component interconnection (PCI), PCI express (PCIe), IEEE 1394, universal serial bus (USB), NVMe, and CXL.

The command decoder 114 may decode a command parsed from the command, based on the protocol of the interface negotiated on the host. The packet manager may parse the command from the packet received from the host, based on the protocol of the interface negotiated on the host. For example, the command decoder 114 may decode an opcode of the command which is based on a specific protocol and may identify a program command, an erase command, a read command, and/or a secure erase command. The processor 113 may perform the request of the host depending on the decoded command. In an embodiment, the command decoder 114 may be implemented as a portion of an independent circuit and/or firmware.

The flash translation layer 115 may perform various functions (or operations) such as address mapping, wear-leveling, and garbage collection.

The address mapping operation may be an operation of translating a logical address received from the host into a physical address to be actually used to program data in the memory device 120 of FIG. 1. For example, a logical block address (LBA) of user data which are requested by the host to be programmed may be translated into a physical address of the memory device 120 of FIG. 1 by using the flash translation layer 115. In one or more embodiments, the physical address may be a physical page number (PPN). In one or more embodiments, an address mapping table which the flash translation layer 115 manages may store a mapping relationship between a logical page number (LPN) and a physical page number. In one or more embodiments, each of logical page numbers LPN may correspond to a plurality of logical block addresses LBA.

The wear-leveling which is a technology for allowing blocks of the memory device 120 of FIG. 1 to be used uniformly such that excessive degradation of a specific block may be prevented, for example, through a firmware technology for balancing erase counts of physical blocks. The garbage collection refers to a technology for securing an available capacity of the memory device 120 of FIG. 1 through a method to copy valid data of a block to a new block and to then erase the block.

The working memory device may include registers for storing internal variables of the memory controller 110A. In one or more embodiments, the working memory device which operates as a buffer memory may temporarily store data to be recorded at the memory device 120 of FIG. 1 or data read from the memory device 120 of FIG. 1. The working memory device may be implemented with a volatile memory device. According to one or more embodiments, the working memory device may be disposed inside and/or outside the memory controller 110A. As another example, when the host buffer memory is provided by the host, the working memory device may not operate as a buffer memory.

The ECC circuit 118 may generate parity information by performing ECC encoding for data to be programmed in the memory device 120 of FIG. 1 and may add the parity information to the data. Also, the ECC circuit 118 may detect an error bit from the data read from the memory device 120. For example, the memory controller 110 may detect an error bit by performing ECC decoding for the read data. FIG. 9 shows the case where the memory controller 110A includes the ECC circuit 118, but embodiments are not limited thereto. For example, the memory device 120 of FIG. 1 may include an on-die ECC circuit. In one or more embodiments, the ECC circuit 118 may be implemented as an independent circuit and/or a portion of firmware.

The memory controller 110A according to one or more embodiments may determine a defect of a wordline based on sensing data received from the memory device 120 of FIG. 1 and/or the number of on-cells based on the sensing data.

For example, the defective wordline checking unit 111 may compare a difference between the first number of on-cells (or referred to as an “on-cell count”) based on the first sensing data and the second number of on-cells based on the second sensing data, as described with reference to FIGS. 5 and 6, with a reference set in advance in a reference table 112 stored in the SRAM 117. As described above, the defective wordline checking unit 111 may determine a defect of a wordline by variously using a difference between off-cell counts and/or a difference between error bit counts calculated by the ECC circuit 118 through ECC decoding, in addition to the difference of on-cell counts.

In one or more embodiments, when a selected wordline is checked as being defective, the defective wordline checking unit 111 may perform a reclaim operation of a sub-block and/or a memory block in which the selected wordline is included.

In one or more embodiments, the defective wordline checking unit 111 may determine a defective wordline in a specific area of a memory cell array. For example, the defective wordline checking unit 111 may determine a defective wordline of a specific area by using pieces of data corresponding to the specific area from among the first sensing data and the second sensing data. The specific area may be an area which is defined by some wordlines and some bitlines. For example, the specific area may be a partial area of an arbitrary block. For example, the specific area may correspond to some cells connected to specific bitlines from among cells electrically connected to an arbitrary wordline.

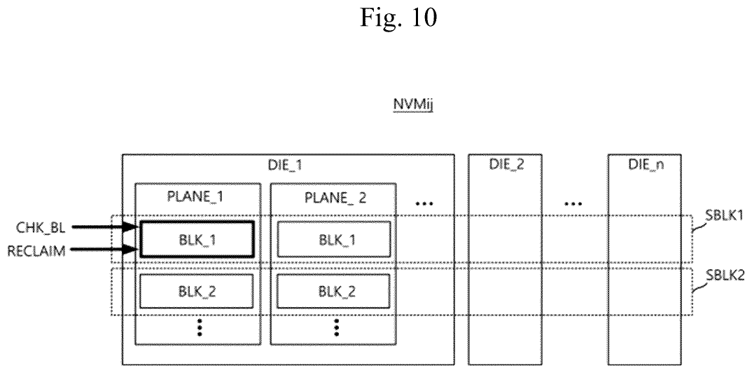

FIG. 10 is a diagram describing an operating method of the memory controller 110A according to the embodiment of FIG. 9 as an example. A nonvolatile memory device NVMij of FIG. 10 may correspond to one of the nonvolatile memory devices NVM11 to NVMmn of FIG. 7.

The nonvolatile memory device NVMij may include a plurality of dies DIE_1 to DIE_n, and each of the plurality of dies DIE_1 to DIE_n may include a plurality of planes. Each plane may include a plurality of memory blocks BLK_1, BLK_2, etc. The plurality of memory blocks BLK_1, BLK_2, etc. included in the plurality of dies DIE_1 to DIE_n may be grouped into super blocks SBLK. For example, the plurality of memory blocks BLK_1 respectively included in the plurality of dies DIE_1 to DIE_n may be grouped as the first super block SBLK1, and the plurality of memory blocks BLK_2 respectively included in the plurality of dies DIE_1 to DIE_n may be grouped as the second super block SBLK2. According to one or more embodiments, each of the memory blocks BLK_1, BLK_2, etc. may mean a physical block. A super block SBLK may refer to a unit of a logical memory area, which is used for the memory controller 110A to manage the memory device 120. The memory blocks BLK_1, BLK_2, etc. may include a plurality of physical pages. The physical page may include memory cells connected to the same wordline. The memory cell may include a single level cell (SLC), a multi-level cell (MLC), a triple level cell (TLC), a quadruple level cell (QLC), etc.

In one or more embodiments, the defective wordline determining methods of FIGS. 5 and 6 may be set in advance by using a specific internal command.

In one or more embodiments, a first command may be an internal command for performing the defective wordline determining methods of FIGS. 5 and 6 in association with the selected word line. The memory controller 110A may transmit an address of a specific wordline to the memory device 120 of FIG. 1 together with the first command. The specific wordline may include a plurality of wordlines.

In one or more embodiments, a second command may be an internal command for performing the defective wordline determining methods of FIGS. 5 and 6 in association with all the wordlines included in a selected block or super block. The memory controller 110A may transmit an address of a specific block or a specific super block to the memory device 120 of FIG. 2 together with the second command. For example, referring to FIG. 10, the memory controller 110A may designate a first block of a first plane in a first die of the memory device 120 of FIG. 1 together with the transmission of a second command CHK_BL.

In one or more embodiments, every given period or when a preset condition is satisfied, the memory controller 110A may control the memory device 120 of FIG. 1 to determine a defect of all the memory blocks or all the wordlines. For example, a third command of FIG. 10 may be an internal command for performing the defective wordline determining methods of FIGS. 5 and 6 in association with all the wordlines included in all the memory blocks. The memory controller 110A may transmit the third command to the memory device 120 of FIG. 1.

For example, in response to the third command which control logic receives from the memory controller 110A, the memory device 120 may sequentially perform the defective wordline determining methods of FIGS. 5 and 6 for each of a plurality of wordlines included in each of a plurality of memory blocks.

In one or more embodiments, a fourth command may be an internal command for performing the defective wordline determining methods of FIGS. 5 and 6 with respect to a selected wordline and a selected bitline. The memory controller 110A may transmit an address of a specific wordline and an address of a specific bitline to the memory device 120 of FIG. 4 together with the fourth command. As another example, the memory controller 110 may transmit addresses of a plurality of wordlines and addresses of a plurality of bitlines of the memory device 120. As another example, the memory controller 110A may transmit information indicating a specific area of the memory cell array to the memory device 120 of FIG. 1 together with the first command. The memory device 120 may determine a defective wordline, based on a cell count associated with cells of the specific area of the memory cell array 121 of FIG. 1. The specific area may be designated by addresses of a wordline(s) and a bitline(s). For example, the specific area may be a partial internal area of a first block BLK_1 of a first plane PLANE_1 belonging to a first die DIE_1 of FIG. 10. For example, the specific area may correspond to some cells connected to specific bitlines from among cells electrically connected to an arbitrary wordline.

In one or more embodiments, the first command to the fourth command may be executed based on the setting of a double-speed mode. The double mode may be used to simultaneously determine whether defective wordlines are present in a plurality of planes among planes PLANE_1, PLANE2, etc. of FIG. 10. For example, whether a wordline of the first plane PLANE_1 is defective and whether a wordline of the second plane PLANE_2 is defective may be determined at substantially the same time. The method of FIG. 5 or 6 may be simultaneously performed for the wordline of the first plane PLANE_1 and the wordline of the second plane PLANE_2.

FIG. 10 shows an example in which the memory controller 110A transmits the second command CHK_BL to the memory device 120 of FIG. 1. In one or more embodiments, the memory device 120 may sequentially determine the defect in association with all the wordlines of each of all the memory blocks.

When the memory controller 110A or the memory device 120 determines that a wordline is defective, the memory controller 110A may control the memory device 120 to perform the reclaim operation for a block including the wordline determined as defective.

For example, when the wordline of the first block BLK_1 of the first plane PLANE_1 of the first die DIE_1 being defective is determined in response to the second command CHK_BL, the memory controller 110A may transmit a reclaim command RECLAIM associated with the first block BLK_1 to the memory device 120 such that pieces of data programmed in the first block BLK_1 of the first plane PLANE_1 of the first die DIE_1 are again recorded at any other block. In this example, when the memory device 120 performs the reclaim operation, the memory device 120 may set a sensing time of the read operation to a sensing time delayed with respect to a normal sensing time of the read operation and thus may stably the reclaim operation for data. For example, the memory device 120 may perform the read operation for cells, which are electrically connected to a wordline determined as defective, based on a maximally delayed sensing time and may program the read data in cells electrically connected to any other wordline. A block electrically connected to the wordline determined as defective may be processed as a run time defective block RTBB. As another example, the memory device 120 may first perform the normal read operation, and when an error (or an uncorrectable error) is detected from the read data, the memory device 120 may perform the read operation based on the maximally delayed sensing time. Whether an error occurs in the read data may be determined by the on-die ECC circuit of the memory device 120 or the ECC circuit 118 of the memory controller 110A.

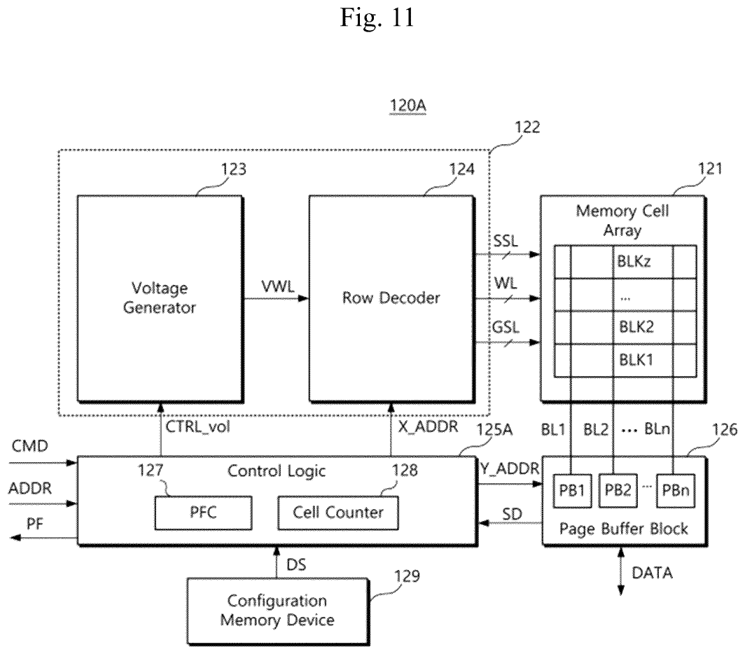

FIG. 11 is a diagram illustrating a configuration of a memory device according to one or more embodiments. A memory device 120A to be described with reference to FIG. 11 may correspond to the memory device 120 of FIG. 1.

Referring to FIG. 11, the memory device 120A may include the memory cell array 121, the voltage generator and row decoder 122, the control logic 125A, the memory cell array 121, the page buffer block 126, and a configuration memory device 129. The voltage generator and row decoder 122 may include a voltage generator 123 and a row decoder 124.

The control logic 125A may overall control various types of operations of the memory device 120A. The control logic 125A may output various types of control signals in response to a command CMD and/or a physical address ADDR from the memory interface circuit 119 (refer to FIG. 9). For example, the control signals may include a voltage control signal CTRL_vol, a row address X_ADDR, and a column address Y_ADDR.

The memory cell array 121 may include a plurality of memory blocks BLK1 to BLKz (z being a positive integer), and each of the plurality of memory blocks BLK1 to BLKz may include a plurality of memory cells. The memory blocks BLK1 to BLKz may be connected to the page buffer block 126 through bitlines BL1 to BLn and may be connected to the row decoder 124 through wordlines WL, string select lines SSL, and ground select lines GSL.

The page buffer block 126 may include a plurality of page buffers PB1 to PBn (n being an integer greater than or equal to 3), and the plurality of page buffers PB1 to PBn may be connected to memory cells included in each of the plurality of memory blocks BLK1 to BLKz through the plurality of bitlines BL1 to BLn. The page buffer block 126 may select at least one of the bitline BL1 to BLn in response to the column address Y_ADDR. The page buffer block 126 may operate as a write driver or a sense amplifiers depending on an operation mode. For example, in the program operation, the page buffer block 126 may apply a bitline voltage corresponding to data “DATA” to be programmed to the selected bitline. In the read operation, the page buffer block 126 may sense a current or a voltage of the selected bitline to read data stored in a memory cell. The plurality of page buffers PB1 to PBn of the page buffer block 126 may sense data stored in memory cells through the plurality of bitlines BL1 to BLn and may temporarily store the sensed data as sensing data.

For example, the plurality of page buffers PB1 to PBn according to one or more embodiments may temporarily store data sensed from memory cells through the plurality of bitlines BL1 to BLn at a first time as the first sensing data. The page buffer block 126 may transmit the first sensing data to the control logic 125A. The plurality of page buffers PB1 to PBn may temporarily store data sensed from the memory cells through the plurality of bitlines BL1 to BLn at a second time as the second sensing data. The page buffer block 126 may transmit the second sensing data to the control logic 125A.

The voltage generator 123 may generate various types of voltages for performing the program operation, read operation, and the erase operation, etc. based on the voltage control signal CTRL_vol.

In response to the row address X_ADDR, the row decoder 124 may select one of the plurality of wordlines WL and may select one of the plurality of string select lines SSL.

The control logic 125A according to one or more embodiments may include a determination circuit (PFC) 127 and a cell counter 128. The cell counter 128 may refer to a circuit which determines the number of on-cells and/or the number of off-cells based on sensing data SD. The cell counter 128 may be implemented as a circuit.

The determination circuit 127 may compare a difference between the number of on-cells based on the first sensing data and the number of on-cells based on the second sensing data with a preset reference DS and may determine a defect of a wordline. The preset reference DS may be received from the configuration memory device 129. For example, the memory device 120A may load the reference DS stored in a partial area of the memory cell array 121 to the configuration memory device 129 implemented with an e-fuse.

In one or more embodiments, the control logic 125A may transmit a result PF of determining a defect of a wordline to the memory controller 110.

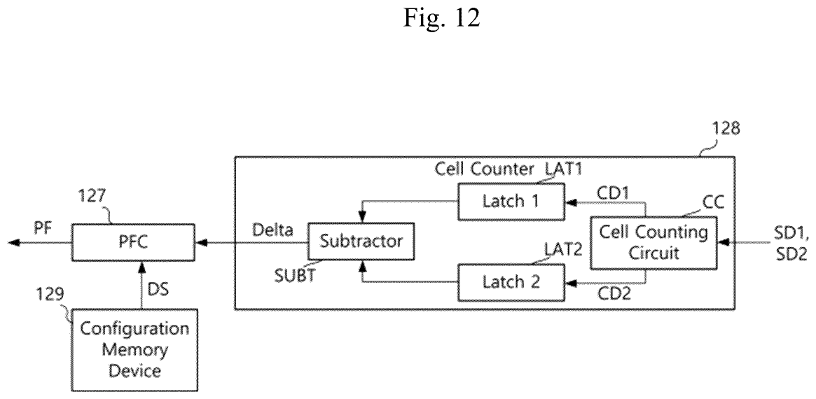

FIG. 12 is a block diagram describing one or more embodiments of the cell counter 128 of the memory device 120A of FIG. 11.

The cell counter 128 according to one or more embodiments may include a cell counting circuit CC, a first latch LAT1, a second latch LAT2, and a subtractor SUBT.

To determine the number of on-cells or number of off-cells under a specific wordline voltage condition or the number of on-cells present within a specific voltage interval, the cell counting circuit CC may count the number of 0s or 1s from sensing data which the plurality of page buffers PB1 to PBn (refer to FIG. 11) transmit.

The cell counting circuit CC may receive the first sensing data SD1 from the plurality of page buffers PB1 to PBn (refer to FIG. 11). The cell counting circuit CC may count the number of on-cells (or off-cells) based on the first sensing data SD1 and may store the number of on-cells in the first latch LAT1 as a first cell count CD1.

The cell counting circuit CC may receive the second sensing data SD2 from the plurality of page buffers PB1 to PBn (refer to FIG. 11). The cell counting circuit CC may count the number of on-cells (or off-cells) based on the second sensing data SD2 and may store the number of on-cells in the second latch LAT2 as a second cell count CD2.

The subtractor SUBT may receive the first cell count CD1 stored in the first latch LAT1 and the second cell count CD2 stored in the second latch LAT2 and may transmit a difference Delta between the first cell count CD1 and the second cell count CD2 to the determination circuit 127.

The determination circuit 127 may compare the difference Delta between the number of on-cells based on the first sensing data SD1 and the number of on-cells based on the second sensing data SD2 with the preset reference DS and may determine a defect of a wordline. The preset reference DS may be received from the configuration memory device 129. The determination circuit 127 may output a signal PF indicating a result of comparing an on-cell count difference (i.e., Delta) with the preset reference DS, for example, indicating whether a wordline is defective.

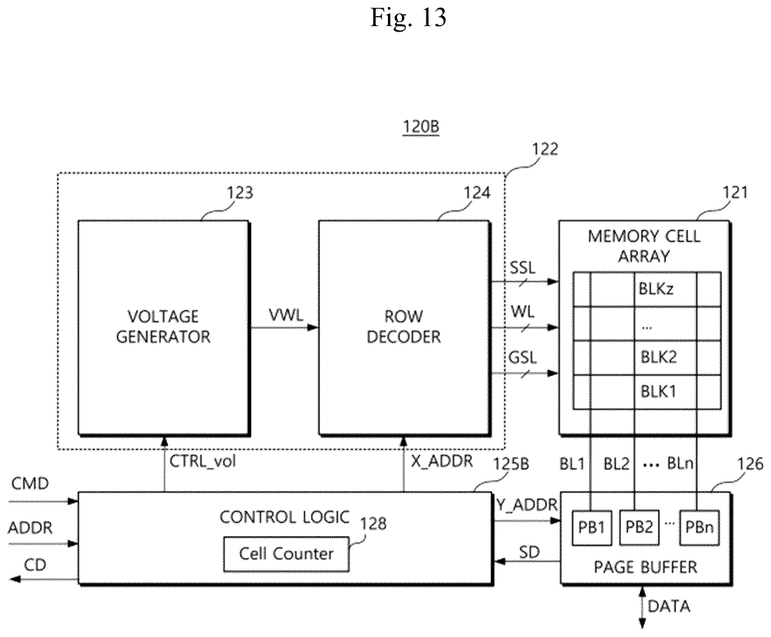

FIG. 13 is a diagram illustrating a configuration of a memory device according to one or more embodiments. A memory device 120B to be described with reference to FIG. 13 may correspond to the memory device 120 of FIG. 1.

The memory device 120B will be described with reference to FIG. 13 based on a difference with the memory device 120A described with reference to FIG. 11.

In the memory device 120B of FIG. 13, a control logic circuit 125B may not include the determination circuit 127 of FIG. 11.

The cell counter 128 of the control logic circuit 125B according to one or more embodiments of FIG. 13 may be the same as the cell counter 128 of FIG. 12. The control logic circuit 125B may transmit the difference Delta between the first cell count CD1 and the second cell count CD2, which the cell counter 128 outputs, to the memory controller 110.

The memory controller 110 may compare the difference Delta between the first cell count CD1 based on the first sensing data SD1 and the second cell count CD2 based on the second sensing data SD2 with a preset reference and may determine a defect of a wordline. For example, the preset reference may be stored in the SRAM 117 of FIG. 9.

In one or more embodiments, the memory device 120B may transmit, to the memory controller 110, the difference Delta between the first cell count CD1 and the second cell count CD2 based on sensing data of a partial area of the memory cell array 121, based on the command CMD received from the memory controller 110.

For example, in response to a specific command CMD, the control logic circuit 125B may drive only some bitlines among the bitlines BL1, BL2, . . . , BLn corresponding to a selected wordline and may obtain the sensing data. The control logic circuit 125B may calculate the difference Delta between the first cell count CD1 and the second cell count CD2 based on the obtained sensing data.

As another example, in response to another specific command CMD, the control logic circuit 125B may drive all the bitlines BL1, BL2, . . . , BLn corresponding to the selected wordline and may obtain the sensing data. In this case, The control logic circuit 125B may calculate the difference Delta between the first cell count CD1 and the second cell count CD2 based on sensing data belonging to a partial area from among the obtained sensing data.

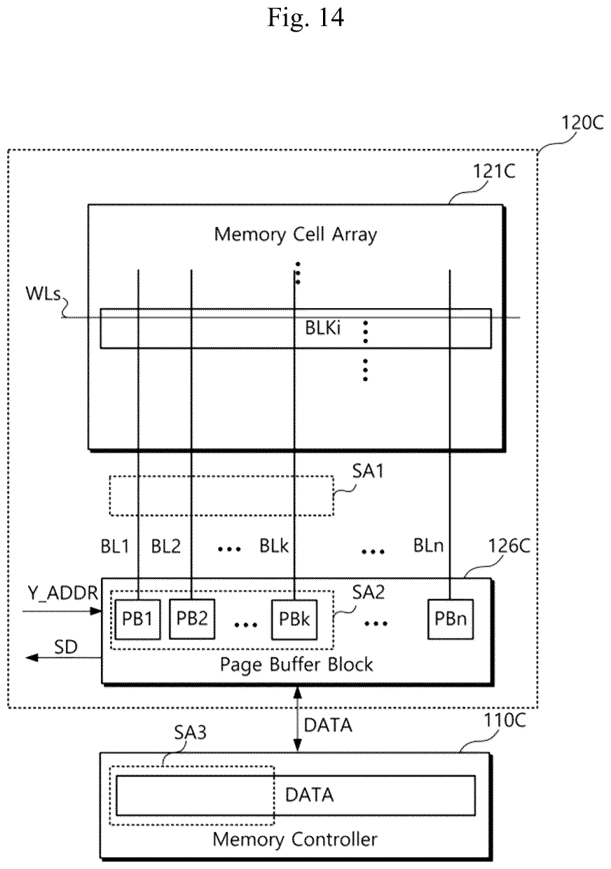

FIG. 14 is a diagram describing an operation in which a storage device according to one or more embodiments obtains sensing data of a partial area of a memory cell array. The operation of FIG. 14 may be performed by the storage device 100 of FIG. 1. For convenience of description, only some of the components of a memory cell 120C are illustrated in FIG. 14. Also, for convenience of description, only a selected wordline WLs among a plurality of wordlines connected to the memory block BLKi is illustrated in FIG. 14.

In one or more embodiments, the memory device 120C of FIG. 14 may correspond to the memory device 120A of FIG. 11 or the memory device 120B of FIG. 13.

In one or more embodiments, a memory controller 110C of FIG. 14 may correspond to the memory controller 110A of FIG. 9.

In one or more embodiments, the storage device 100 may determine a defect of a wordline based on sensing data of a partial area of a memory cell array 121C. The partial area may refer to an area corresponding to the selected wordline WLs and some of the bitlines BL1, BL2, . . . , BLn. In one or more embodiments, a plurality of wordlines may be selected. In the description to be given with reference to FIG. 14, a selected wordline may be conceptually understood as including a plurality of wordlines. In one or more embodiments, the plurality of wordlines may be wordlines of different planes.

In one or more embodiments, the memory device 120C may drive only specific bitlines BL1, BL2, . . . , BLk, may read data from cells connected to the specific bitlines BL1, BL2, . . . , BLk, and may store the read data in page buffers PB1, PB2, . . . , PBk corresponding to the specific bitlines BL1, BL2, . . . , BLk. A page buffer block 126C may receive the address Y_ADDR indicating the specific bitlines BL1, BL2, . . . , BLk. Accordingly, the read operation may be performed by using bitlines SA1 corresponding to the partial area of the memory cell array 121C. Control logic of a memory controller and/or a memory device may determine a defect of a wordline by using sensing data SD obtained from the bitlines SA1 corresponding to the partial area of the memory cell array 121C.

In one or more embodiments, all the bitlines BL1, BL2, . . . , BLn may be divided in units of specific unit, and data of cell connected to bitlines for each unit may be read. For example, when 16 KB data are capable of being read through all the bitlines BL1, BL2, . . . , BLn, the address Y_ADDR indicating a specific division unit of 4 KB, 8 KB, etc. may be received.

In one or more embodiments, the memory device 120C may store data read from all the bitlines BL1, BL2, . . . , BLn in the page buffer circuits PB1, PB2, . . . , PBn and may output the sensing data SD of some page buffer circuits PB1, PB2, . . . , PBk among the page buffer circuits PB1, PB2, . . . , PBn. Accordingly, the memory device 120C may output the sensing data SD of page buffer circuits SA2 corresponding to the partial area of the memory cell array 121C. The control logic of the memory controller and/or the memory device may determine a defect of a wordline by using the sensing data SD obtained from the page buffer circuits SA2 corresponding to the partial area of the memory cell array 121C.

In one or more embodiments, the memory device 120C may store data read from all the bitlines BL1, BL2, . . . , BLn in the page buffer circuits PB1, PB2, . . . , PBn and may output the sensing data SD of the page buffer circuits PB1, PB2, . . . , PBn. The control logic of the memory controller and/or the memory device may determine a defect of a wordline by using partial sensing data SA3 of the sensing data SD of the page buffer circuits PB1, PB2, . . . , PBn. The partial sensing data SA3 may correspond to cell data of the partial area of the memory cell array 121C.

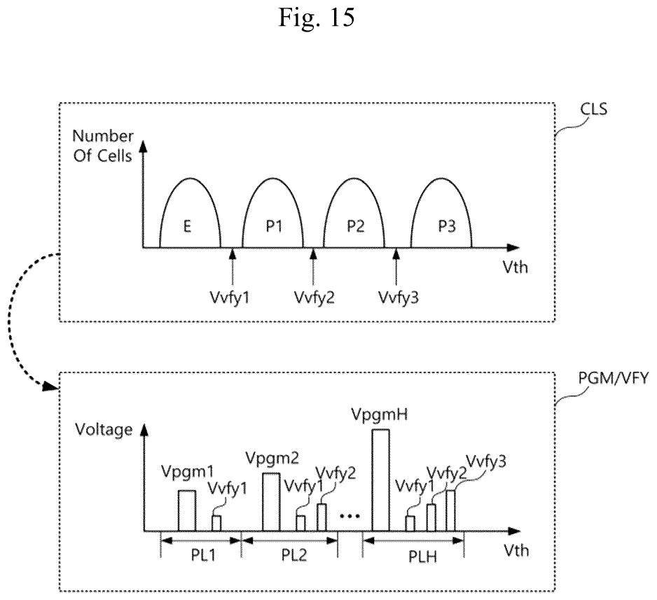

FIG. 15 is a diagram describing an operation of programming a memory cell, according to one or more embodiments.

One or more embodiments of FIG. 15 will be described under the assumption that a memory cell is a multi-level cell (MLC); however, the embodiment of FIG. 15 may be applied to a single level cell (SLC), a triple level cell (TLC), a quadruple level cell (QLC), etc. to be similar to a method to be described with reference to FIG. 15.

Referring to FIG. 15, memory cells may have one of the erase state “E”, the first program state P1, the second program state P2, and the third program state P3. The memory cells based on the erase state “E”, the first program state P1, the second program state P2, and the third program state P3 may form a distribution CLS. For example, the memory cells may be in the erase state “E” as an initial state, and as the memory cells are programmed, the memory cells may have one of the erase state “E”, the first program state P1, the second program state P2, and the third program state P3.

When a memory device has the distribution CLS based on the erase state “E”, the first program state P1, the second program state P2, and the third program state P3, the memory device may program the memory cells based on an incremental step pulse programming (ISPP) manner. For example, the memory cells may be programmed in a program and verify (PGM/VFY) manner.

The memory device may perform a plurality of program loops PL1 to PLH to program the memory cells. Each of the program loops PL1 to PLH may include a program operation PGM in which a relevant program voltage among program voltages Vpgm1 to VpgmH is applied to a selected wordline and a verify operation VFY for verifying program states of the memory cells. Whenever the program loops PL1 to PLH are sequentially performed, a program voltage which is applied to the selected wordline in the program operation PGM may be increased as much as a preset offset voltage.

The verify operation VFY may include a verify read operation and a determination operation. The verify read operation may be an operation of reading memory cells based on first to third verify voltages Vvfy1 to Vvfy3. For example, memory cells programmed normally to the first program state P1 being a target program state may be read by the first verify voltage Vvfy1. A memory cell whose target program state is the first program state P1 and which is actually programmed to the first program state P1 may be read as an off-cell by the first verify voltage Vvfy1. A memory cell whose target program state is the first program state P1 but which is actually programmed to the erase state “E” may be read as an on-cell by the first verify voltage Vvfy1. Accordingly, a storage device may determine whether the programmed memory cell accurately has a target program state, through the determination operation based on a result of the verify read operation.

Similar to the first program state P1, the verify read operation for a memory cell whose target program state is the second program state P2 or the third program state P3 may be performed by using the second verify voltage Vvfy2 or the third verify voltage Vvfy3. FIG. 15 shows that levels of the first to third verify voltages Vvfy1 to Vvfy3 gradually increase. However, embodiments are not limited thereto, and the level of the third verify voltage Vvfy3 may be lower than the level of the second verify voltage Vvfy2. For example, levels of the first to third verify voltages Vvfy1 to Vvfy3 may be different from those illustrated in FIG. 15.

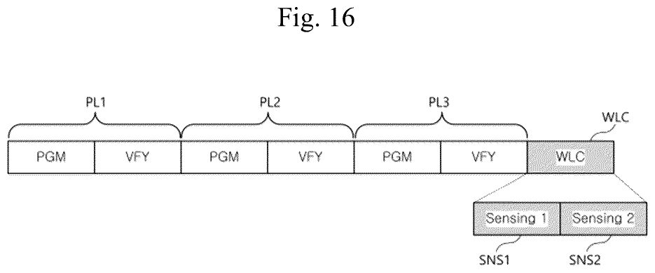

FIG. 16 is a diagram describing an operation of determining a defective wordline, according to one or more embodiments. A defective wordline determining operation to be described with reference to FIG. 16 may be performed by the storage device 100 of FIG. 1.

In one or more embodiments, the storage device 100 may perform a wordline check operation WLC whenever the program operation is performed. For example, a memory device may perform the wordline check operation WLC for a wordline targeted for the program operation in response to a program command received from a memory controller. The wordline targeted for the program operation may be a wordline electrically connected to a control node of a cell in which user data are programmed in response to the program command.

In one or more embodiments, the storage device 100 may in advance store settings associated with whether to perform the wordline check operation WLC in the program operation. When the settings are stored to indicate an activation state, the memory device 120 of FIG. 2 may perform the wordline check operation WLC whenever the program operation is performed. When the settings are stored to indicate a deactivation state, the memory device 120 may only perform the program operation.

According to one or more embodiments, the memory device may output sensing data as a result of the wordline check operation WLC, may output a difference between on-cell counts based on a plurality of sensing data, or may output information indicating whether a wordline is defective.

FIG. 16 shows an example in which the storage device 100 performs the wordline check operation WLC in the program operation for programming a memory cell to the third program state P3 being a target program state.

Referring to FIG. 16, to program a memory cell to the third program state P3 being a target program state, the storage device 100 executes a plurality of program loops PL1 to PL3, and in each of the program loops PL1 to PL3, the storage device 100 performs the program operation PGM for applying the program voltage and the verify operation VFY for verifying the program state.

After the storage device 100 performs the plurality of program loops PL1 to PL3 for programming the memory cell to the target program state, the storage device 100 may perform the wordline check operation WLC for a wordline corresponding to the programmed memory cell. The wordline check operation WLC may be performed to be the same as the defective wordline determining method described with reference to FIGS. 5 and 6.

In one or more embodiments, a level of a voltage applied to a selected wordline during the wordline check operation WLC may be the same as a level of one verify voltage among a plurality of verify voltages. For example, the level of the voltage applied to the selected wordline during the wordline check operation WLC may be a program verify level of the first program state P1.

As another example, in one or more embodiments, the level of the voltage applied to the selected wordline during the wordline check operation WLC may be the same as a read level for performing the read operation. For example, when the memory cell is the multi-level cell (MLC), the level of the voltage applied to the selected wordline may be one of a level at which a memory cell of the erase state “E” is determined as an on-cell, a level at which a memory cell of the first program state P1 is determined as an on-cell, and a level at which a memory cell of the second program state P2 is determined as an on-cell.

During the wordline check operation WLC, the storage device 100 may perform first sensing SNS1 and second sensing SND2 for cells connected to the selected wordline or cells programmed in response to the program command. The first sensing SNS1 and the second sensing SND2 may respectively corresponding to the first stage 1 and the second stage 2 of the defective wordline determining method described with reference to FIGS. 5 and 6.

In one or more embodiments, sensing times which are used in the first sensing SNS1 and the second sensing SND2 may be different from a sensing time which is used in the verify operation VFY. For example, as described with reference to FIGS. 5 and 6, the sensing times which are used in the first sensing SNS1 and the second sensing SND2 may be changed by controlling holding times of phases before the develop and sensing phase. In this example, a wordline connected to a memory cell determined as being accurately programmed to a target program state in the verify read operation belonging to the verify operation VFY for the memory cell may be determined as a defective wordline by the wordline check operation WLC.

According to the embodiment described with reference to FIG. 16, for example, because the storage device 100 performs the wordline check operation WLC whenever the program operation is performed, when a result of the wordline check operation WLC indicates that a wordline is defective, the storage device 100 may reclaim data of the programmed block and may process the programmed block as the run time defective block RTBB. Accordingly, there may be prevented a situation where memory cells connected to the defective wordline are normally programmed but a recovery-impossible uncorrectable error correction code (UECC) error occurs due to the defective wordline.

FIG. 17 is a diagram describing an operating method of a storage device according to one or more embodiments. The operating method to be described with reference to FIG. 17 may be performed by the storage device 100 of FIG. 1. Additional description of components which are the same as or similar to the components described with reference to FIGS. 1 to 16 will be omitted to avoid redundancy.

In operation S110, the storage device 100 may sense cells electrically connected to a first wordline at a first time by using a first voltage, may perform a first cell counting operation based on first sensing data sensed at the first time, and may store a first cell count being a result of the first cell counting operation. The first cell count may be temporarily stored in a page buffer circuit. According to embodiments, the first cell count may be stored in a first latch in control logic of a memory device or may be transmitted to a memory controller.

The cell counting operation may refer to an operation of counting the number of on-cells, and the storage device 100 may count the number of off-cells.

In operation S120, the storage device 100 may sense the cells electrically connected to the first wordline at a second time by using the first voltage, may perform a second cell counting operation based on second sensing data sensed at the second time, and may store a second cell count being a result of the second cell counting operation. The second cell count may be temporarily stored in the page buffer circuit. According to one or more embodiments, the second cell count may be stored in a second latch in the control logic of the memory device or may be transmitted to the memory controller.

In operation S130, the storage device 100 may compare the first cell count and the second cell count. For example, the storage device 100 may compare the first cell count and the second cell count by calculating a difference between the first cell count and the second cell count. According to one or more embodiments, the control logic of the memory device may compare the first cell count and the second cell count, or the memory controller may compare the first cell count and the second cell count.

In one or more embodiments, when the difference between the first cell count and the second cell count exceeds a preset reference, the control logic of the memory device or the memory controller may determine that the first wordline is a defective wordline.

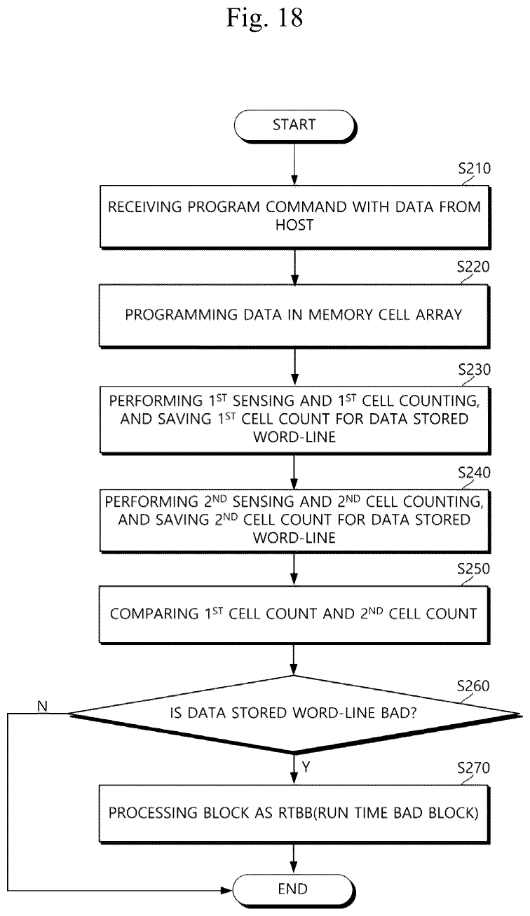

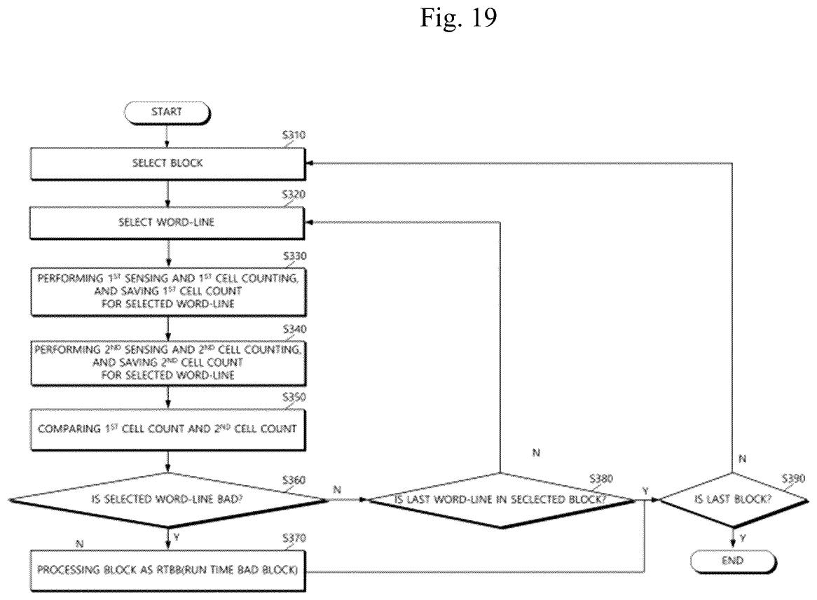

FIGS. 18 and 19 are diagrams describing operating methods of a storage device according to embodiments of the present disclosure in two different modes. The operating methods to be described with reference to FIGS. 18 and 19 may be performed by the storage device 100 of FIG. 1. Additional description of components which are the same as or similar to the components described with reference to FIGS. 1 to 17 will be omitted to avoid redundancy.

As in the above description given with reference to FIG. 16, according to the operating method of FIG. 18, the storage device 100 may perform the wordline check operation WLC whenever the program operation is performed. For example, in response to the program command received from a memory controller, the memory device 120 of the storage device 100 may perform the wordline check operation WLC for a wordline targeted for the program operation. The wordline targeted for the program operation may be a wordline electrically connected to a control node of a cell in which user data are programmed in response to the program command.

Referring to FIG. 18, in operation S210, the storage device 100 may receive the program command from a host device.

In operation S220, the memory controller of the storage device 100 may transmit the program command and user data to the memory device 120 based on the decoded program command. The memory device 120 may program the user data in a memory cell array. For example, the memory device 120 may program the user data by using the method described with reference to FIG. 15.

In operation S230, the storage device 100 may perform first sensing for a wordline where data are stored, may perform first cell counting based on a result of the first sensing, and may store a first cell count. For example, the first sensing may correspond to the first stage Stage 1 of FIGS. 5 and 6.

In operation S240, the storage device 100 may perform second sensing for the wordline where the data are stored, may perform second cell counting based on a result of the second sensing, and may store a second cell count. For example, the second sensing may correspond to the second stage Stage 2 of FIGS. 5 and 6.

In operation S250, the storage device 100 may compare the first cell count and the second cell count. For example, the storage device 100 may compare the first cell count and the second cell count by calculating a difference between the first cell count and the second cell count. According to one or more embodiments, the control logic of the memory device may compare the first cell count and the second cell count, or the memory controller may compare the first cell count and the second cell count. To compare the first cell count and the second cell count may be to calculate a difference between the first cell count and the second cell count.

In operation S260, the storage device 100 may determine whether the wordline where the data are programmed is a defective wordline, based on a result of comparing the first cell count and the second cell count. For example, when the difference between the first cell count and the second cell count exceeds the preset reference, the storage device 100 may determine that the wordline where the data are programmed is a defective wordline.

When it is determined that the wordline where the data are programmed is a defective wordline, in operation S270, the storage device 100 may process the block where the data are programmed, as a run time defective block. Accordingly, there may be prevented a situation where memory cells connected to the defective wordline are normally programmed but a recovery-impossible uncorrectable error correction code (UECC) error occurs due to the defective wordline.

As in the above description given with reference to FIG. 10, according to the operating method of FIG. 19, every given interval or when a preset condition is satisfied, the storage device 100 may determine a defect of all the memory blocks or all the wordlines.

Referring to FIG. 19, in operation S310, the storage device 100 may select a block in which whether a wordline is defective will be determined.

In operation S320, the storage device 100 may select one wordline in the selected block.

Operation S330 to operation S360 may be performed to be the same as operation S230 to operation S260, respectively.

When it is determined in operation S360 that the selected wordline is defective, the storage device 100 may process the block where the data are programmed as a run time defective block, and in operation S390, the storage device 100 may determine whether the target block is the last block to be tested.

When it is determined in operation S360 that the selected wordline is normal, the storage device 100 may determine whether the target wordline is the last wordline of the selected block. When the target wordline is the last wordline of the selected block, the storage device 100 proceeds to operation S390. When the target wordline is not the last wordline of the selected block, the storage device 100 may proceed to operation S320 and may again repeat operation S330 to operation S360 in association with a next wordline.

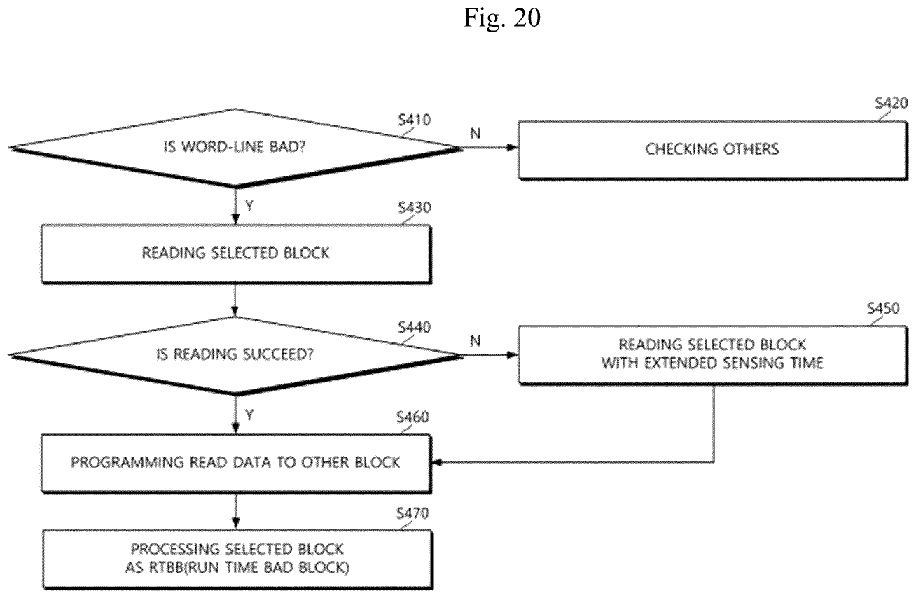

FIG. 20 is a diagram describing an operating method of a storage device according to one or more embodiments. The operating method of FIG. 20 may be performed by the storage device 100 of FIG. 1.

In one or more embodiments, the operating method of FIG. 20 may be performed by the storage device 100 when a wordline is determined as defective in the operating methods of FIGS. 18 and 19. For example, the operating method of FIG. 20 may correspond to operation S260 and operation S270 of the operating method of FIG. 18. As another example, the operating method of FIG. 20 may correspond to operation S360 and operation S370 of the operating method of FIG. 19.

In one or more embodiments, the memory controller 110 or the memory device 120 may perform the operating method of FIG. 20 in association with the wordline determined as defective in FIG. 1.

When a wordline is determined as defective, the operating method of the storage device 100 will be described with reference to FIG. 20.

In operation S410, the storage device 100 may check whether a wordline is defective, and when the wordline is not defective, in operation S420, the storage device 100 may check whether any other wordline and/or a wordline present in any other cell array area or any other super block is defective.

When the wordline is defective, in operation S430, the storage device 100 performs the read operation for the selected block. For example, the storage device 100 may select all the blocks or specific blocks electrically connected to a defective wordline. The read operation may be performed by using a sensing time for a normal read operation.

In operation S440, the storage device 100 may check whether the read operation is successful. For example, when a result of performing ECC decoding for data read from the selected block indicates that an error occurs or that an uncorrectable error occurs, the storage device 100 may determine the read operation of the selected block is failed.

When the read operation is failed, in operation S450, the storage device 100 may perform the read operation of the selected block by using a delayed sensing time. In one or more embodiments, the delayed sensing time may be a maximally delayed sensing time configurable in the storage device 100. Accordingly, when a wordline is determined as defective, the storage device 100 may perform the read operation after a sufficient time passes to such an extent that a voltage of the wordline reaches an applied target voltage and thus may stably recover data from the defective wordline.

In operation S460, the storage device 100 may program the read data in any other block.

In operation S470, the storage device 100 may process the selected block as a run time defective block RTBB.

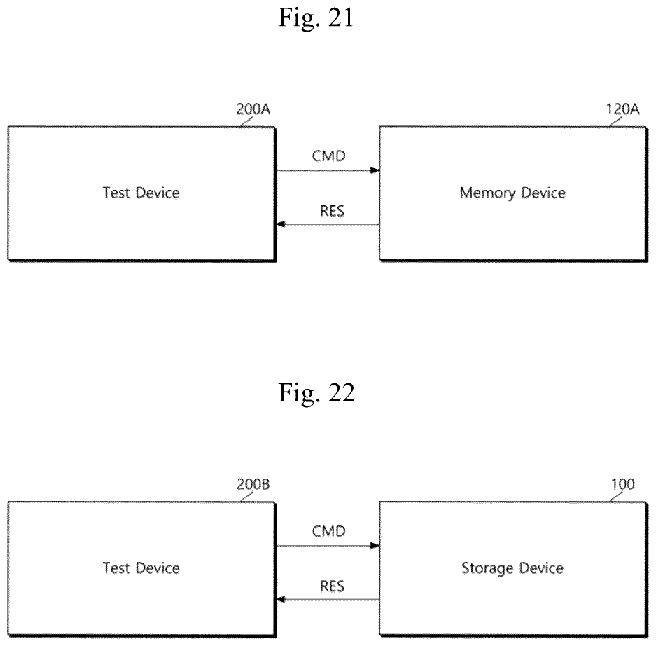

FIGS. 21 and 22 are diagrams describing an environment in which operating methods according to one or more embodiments.

Referring to FIG. 21, some of the operating methods according to one or more embodiments may be performed for a memory device before the product is shipped. For example, a test device 200A may transmit a test command CMD to the memory device 120A described with reference to FIG. 11, and the memory device 120A may transmit a result RES of determining whether a wordline is defective, to the test device 200A. In one or more embodiments, the test command CMD which the test device 200A transmits to the memory device 120A described with reference to FIG. 11 may be transmitted together with an address of a specific wordline.

Referring to FIG. 22, some of the operating methods according to one or more embodiments may be performed for a storage device before the product is shipped. For example, a test device 200B may transmit the test command CMD to the storage device 100 described with reference to FIG. 1, and the storage device 100 may transmit a result RES of determining whether all or some of the memory blocks are defective to a test device 200B. In one or more embodiments, the test command CMD which the test device 200B transmits to the storage device 100 may be transmitted together with an address of a specific block or may be a test command indicating all the blocks.

At least one of the components, elements, modules or units (collectively “components” in this paragraph) represented by a block in the drawings, such as a memory controller 110 in FIG. 1, may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

A storage device according to one or more embodiments may prevent the reduction of performance of the storage device.

The storage device according to one or more embodiments may determine a defect of a wordline.

While embodiments have been described with reference to the figures, it will be understood by those of ordinary skill in the art that various changes in form and details may be made therein without departing from the spirit and scope as defined by the following claims and their equivalents.

What is claimed is:

1. A storage device comprising:
a memory device comprising a plurality of memory blocks, the memory device being configured to store data or read data; and
at least one processor configured to control the memory device and to execute a data input/output request from a host,
wherein the memory device further comprises:
a row decoder configured to apply a voltage of a first level to a first wordline; and
a plurality of page buffers,
wherein, based on the voltage of the first level being applied to the first wordline, the plurality of page buffers are configured to temporarily store first sensing data sensed from a plurality of bitlines at a first time and second sensing data sensed from the plurality of bitlines at a second time after the first time.

2. The storage device of claim 1, wherein the voltage of the first level is a voltage of a read level among voltages of a plurality of read levels or is a voltage of a verify level among voltages of a plurality of verify levels.

3. The storage device of claim 2, wherein the voltage of the first level is a voltage of a program verify level corresponding to a first program state from among voltages of a plurality of program verify levels.

4. The storage device of claim 1, wherein the memory device further comprises:
a determination circuit configured to output information of whether the first wordline is defective, based on at least one of the first sensing data or the second sensing data.

5. The storage device of claim 1, wherein, based on a defect of the first wordline, the memory device is configured to:
perform a read operation of cells electrically connected to the first wordline based on a delayed sensing time; and
program data read from the cells electrically connected to the first wordline in cells electrically connected to a wordline other than the first wordline.

6. The storage device of claim 4, wherein the determination circuit is further configured to output information of whether the first wordline is defective, based on a program command received from the at least one processor.

7. The storage device of claim 4, wherein the memory device further comprises:
a first latch configured to store a first cell count of on-cells or a first cell count of off-cells, based on the first sensing data;
a second latch configured to store a second cell count of on-cells or a second cell count of off-cells, based on the second sensing data;
a subtractor configured to output a difference between the first cell count received from the first latch and the second cell count received from the second latch, and
wherein the determination circuit is further configured to output the information of whether the first wordline is defective, based on the difference.

8. The storage device of claim 4, wherein the determination circuit is further configured to determine whether the first wordline is defective, based on a difference between the first sensing data and the second sensing data.

9. The storage device of claim 1, wherein, after the memory device performs a program operation based on a program command received from the at least one processor, the row decoder is configured to apply the voltage of the first level to the first wordline, and
wherein the first wordline is electrically connected to a control node of a cell configured to program user data based on the program command.

10. The storage device of claim 9, wherein, after a verify operation for the cell, in which the user data are programmed, is performed, the row decoder is further configured to apply the voltage of the first level to the first wordline.

11. The storage device of claim 1, wherein the row decoder is configured to:
stop applying the voltage of the first level to the first wordline after a first setting time passes from the first time; and
apply again the voltage of the first level to the first wordline after a second setting time passes from the stop of the application of the voltage of the first level.

12. The storage device of claim 11, wherein the plurality of page buffers are configured to temporarily store the second sensing data sensed from the first wordline to which the voltage of the first level is again applied.

13. The storage device of claim 1, wherein the at least one processor is further configured to:
receive a first cell count of on-cells or a first cell count of off-cells based on the first sensing data and a second cell count of on-cells or a second cell count of off-cells based on the second sensing data from the memory device; and
determine whether the first wordline is defective, based on at least one of the first cell count or the second cell count.

14. The storage device of claim 13, wherein the row decoder is configured to apply the voltage of the first level to the first wordline based on a first command,
wherein the row decoder is further configured to apply the voltage of the first level to a second wordline based on the first command, and
wherein, based on the voltage of the first level being applied to the second wordline based on the first command, the plurality of page buffers are configured to temporarily store third sensing data sensed from the plurality of bitlines at a third time and fourth sensing data sensed from the plurality of bitlines at a fourth time following the third time.

15. A storage device comprising:
a memory device configured to store data or read data; and
at least one processor configured to control the memory device and to execute a data input/output request provided from a host,
wherein the memory device comprises:
a plurality of memory blocks;
a row decoder configured to apply a voltage to a plurality of wordlines electrically connected to the plurality of memory blocks;
a plurality of page buffers configured to temporarily store pieces of data sensed from a plurality of bitlines; and
a control logic circuit configured to control the row decoder,
wherein the control logic circuit is configured to:
perform a first read operation for at least one wordline at a first time under a first condition; and
perform a second read operation for the at least one wordline at a second time under a second condition,
wherein the plurality of page buffers are further configured to temporarily store first sensing data by the first read operation and second sensing data by the second read operation,
wherein a level of a voltage applied to the at least one wordline under the first condition is identical to a level of a voltage applied to the at least one wordline under the second condition, and
wherein a time during which the level of the voltage applied to the at least one wordline under the first condition is stabilized is different from a time during which the level of the voltage applied to the at least one wordline under the second condition is stabilized.

16. The storage device of claim 15, wherein the second time is a time following the first time.

17. An operating method of a nonvolatile memory system, the method comprising:
sensing cells electrically connected to a first wordline at a first time based on a first voltage;
performing a first cell counting operation based on first sensing data sensed at the first time;
storing a first cell count being a result of the first cell counting operation;
sensing the cells electrically connected to the first wordline at a second time following the first time based on the first voltage;
performing a second cell counting operation based on second sensing data sensed at the second time;
storing a second cell count being a result of the second cell counting operation; and
comparing the first cell count and the second cell count.

18. The method of claim 17, further comprising:
stopping the application of the voltage of a first level to the first wordline after a first setting time passes from the first time; and
applying again the voltage of the first level to the first wordline after a second setting time passes from the stop of the application of the voltage of the first level.

19. The method of claim 17, further comprising:
prior to performing the first cell counting operation,
programming user data in at least some cells connected to the first wordline.

20. The method of claim 17, further comprising:
outputting information of whether the first wordline is defective, based on a difference between the first cell count and the second cell count.
